(19) United States
(12) Patent Application Publication
(10) Pub. No.: US 2022/0415612 A1
(43) Pub. Date: Dec. 29, 2022

(54) HIGH-EFFICIENCY RF REMOTE PLASMA SOURCE APPARATUS

(71) Applicant: Applied Materials, Inc., Santa Clara, CA (US)

(72) Inventors: Mehran Moalem, Fremont, CA (US); Kartik Ramaswamy, San Jose, CA (US)

(21) Appl. No.: 17/835,730

(22) Filed: Jun. 8, 2022

Related U.S. Application Data
(60) Provisional application No. 63/215,366, filed on Jun. 25, 2021.

(51) Int. Cl. H01J 37/32; H01F 27/24; H01F 27/30

(52) U.S. Cl. CPC H01J 37/3211; H01J 37/3244; H01J 37/32357; H01F 27/24; H01F 27/306

(57) ABSTRACT

Embodiments disclosed herein include plasma sources. In an embodiment, a plasma source comprises an input to a plenum for dividing gas into a plurality of parallel fluidic paths, a plurality of plasma zones, wherein each plasma zone is along one of the plurality of parallel fluidic paths, and a plurality of magnetic cores, wherein each magnetic core surrounds one of the plurality of plasma zones. In an embodiment, an RF coil wraps around the plurality of magnetic cores. In an embodiment, the plasma source further comprises a manifold at a bottom of the plurality of plasma zones, where the manifold merges the plurality of fluidic paths into a single output.

### CROSS-REFERENCE TO RELATED APPLICATIONS

This application claims the benefit of U.S. Provisional Application No. 63/215,366, filed on Jun. 25, 2021, the entire contents of which are hereby incorporated by reference herein.

### BACKGROUND

### 1) Field

Embodiments of the present disclosure pertain to the field of semiconductor processing and, in particular, to RF remote plasma sources for generating high-efficiency plasmas.

### 2) DESCRIPTION OF RELATED ART

Semiconductor deposition systems require frequent chamber cleaning to clear buildup of material on the chamber walls. The most efficient process typically used includes an NF₃ remote plasma clean. In such cleaning processes, the NF₃ is broken down in the plasma to generate atomic fluorine. The atomic fluorine flows from the remote plasma source to the chamber. Atomic fluorine is highly reactive and reacts with the material deposited on the chamber walls to form a volatile product that can be removed through a vacuum exhaust system.

Typically, such remote plasma cleaning processes require high power and high flow rates of the NF₃ due to low utilization rates. Accordingly, the process can be expensive and wasteful.

### SUMMARY

Embodiments disclosed herein include plasma sources. In an embodiment, a plasma source comprises an input to a plenum for dividing gas into a plurality of parallel fluidic paths, a plurality of plasma zones, wherein each plasma zone is along one of the plurality of parallel fluidic paths, and a plurality of magnetic cores, wherein each magnetic core surrounds one of the plurality of plasma zones. In an embodiment, an RF coil wraps around the plurality of magnetic cores. In an embodiment, the plasma source further comprises a manifold at a bottom of the plurality of plasma zones, where the manifold merges the plurality of fluidic paths into a single output.

In an additional embodiment, a plasma source comprises a fluidic path having an upstream side and a downstream side, where a plurality of fluidic segments are in parallel to each other between the upstream side and the downstream side. In an embodiment, the plasma source further comprises a plurality of plasma zones, where each plasma zone is along one of the fluidic segments. In an embodiment, the plasma source further comprises a plurality of magnetic cores, where each magnetic core surrounds one of the plasma zones.

Additional embodiments include a semiconductor processing tool. In an embodiment, the semiconductor processing tool comprises a remote plasma source with an upstream end and a downstream end. In an embodiment, the remote plasma source comprises a plenum at the upstream end, where the plenum feeds gas to a plurality of plasma zones, where each plasma zone is surrounded by a magnetic core, and a manifold at the downstream end where the manifold merges gas to an output. In an embodiment, the semiconductor processing tool further comprises a chamber fluidically coupled to the outlet of the remote plasma.

### BRIEF DESCRIPTION OF THE DRAWINGS

FIG. 1A is a plan view illustration of a remote plasma source with a plurality of plasma zones, where each plasma zone is surrounded by a magnetic core, in accordance with an embodiment.

FIG. 1B is a cross-sectional illustration of the remote plasma source in FIG. 1A along line B-B′, in accordance with an embodiment.

FIG. 2A is a plan view illustration of a remote plasma source with a plurality of plasma zones, where the RF coils around the magnetic cores are connected in pairs, in accordance with an embodiment.

FIG. 2B is a plan view illustration of a remote plasma source with a plurality of plasma zones, where the RF coils around the magnetic cores are electrically isolated from each other, in accordance with an embodiment.

FIG. 2C is a plan view illustration of a remote plasma source with a plurality of plasma zones, where the RF coils warp around an exterior edge of each magnetic core, in accordance with an embodiment.

FIG. 2D is a plan view illustration of a remote plasma source with six plasma zones in a hexagonal pattern, in accordance with an embodiment.

FIG. 3 is a cross-sectional illustration of a plasma processing tool with a remote plasma source with a plurality of plasma zones, in accordance with an embodiment.

FIG. 4 illustrates a block diagram of an exemplary computer system, in accordance with an embodiment of the present disclosure.

### DETAILED DESCRIPTION

RF remote plasma sources for generating high-efficiency plasmas are described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

As noted above, plasma cleaning operations that use an NF₃ source gas suffer from significant efficiency limitations. Particularly, high energies are needed in order to breakdown the NF₃ sufficiently. Additionally, a high feed rate of the NF₃ gas is needed due to low utilization of the gas. Due to the need for high power and high flowrates, the cleaning process can become expensive to implement. Additionally, durability of equipment is reduced due to the higher energies needed for the process.

Accordingly, embodiments disclosed herein include a remote plasma source that allows for a reduction in the power and gas feed rates while still enabling high gas utilization. Particularly, embodiments disclosed herein include the use of a plenum at an upstream end of the remote plasma source and a manifold at the downstream end of the remote plasma source. The plenum separates the gas into a plurality of parallel fluidic paths, with each fluidic path passing through a plasma zone. Each plasma zone may comprise a conductive shell surrounded by a magnetic core. The conductive shell may have a dielectric coating and be electrically insulated from the plasma and be protected from chemical and physical erosion by the chemicals and ions present. In an embodiment, RF coils wrap around the magnetic cores in order to induce a plasma in the conductive shell. After dissociating the source gas with the plasma, the radical species from each plasma zone can be routed to a single outlet to processing chamber by a manifold.

The use of parallel fluidic paths allows for the velocity of the gas through the plasma zones to be reduced. The reduced velocity allows for longer residence times within the plasma region and enables a more efficient process and better dissociation efficiency for breaking feed gases to radical species. Such a setup allows for higher flow rates at the input while keeping the same power requirements compared to existing processes and chambers. Alternatively, higher efficiencies can be obtained when the flow rates are kept similar to existing processes and chambers while reducing power input.

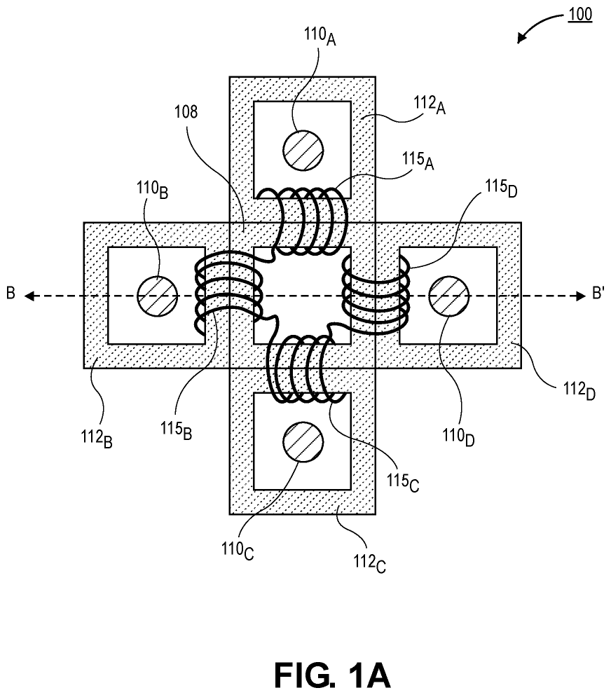

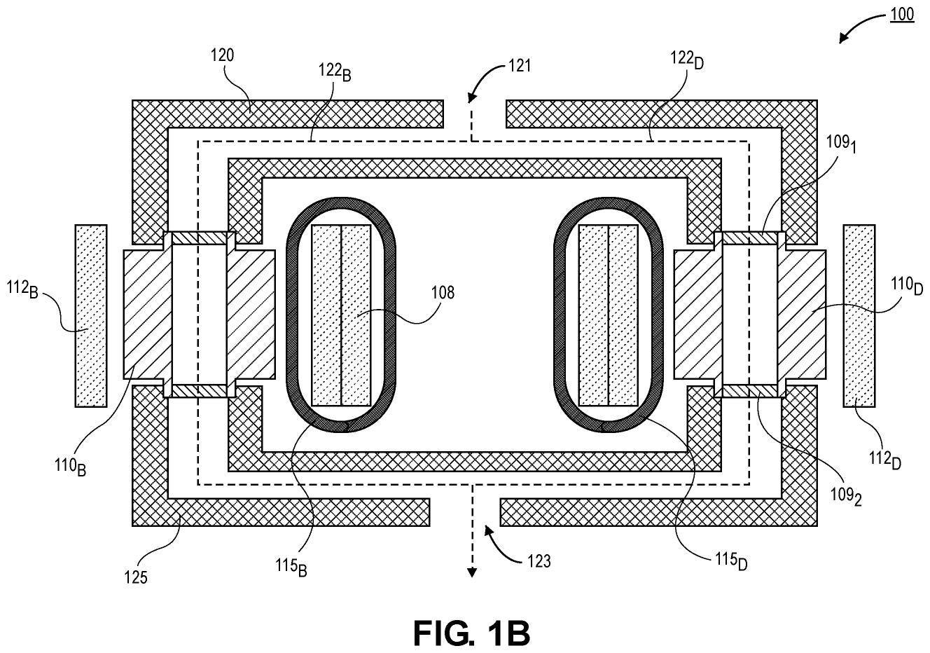

Referring now to FIG. 1A, a plan view schematic of a portion of a remote plasma source 100 is shown, in accordance with an embodiment. The illustrated portion is through a plane that includes the plasma zones 110. That is, a plenum (not shown) may be provided above the plane shown in FIG. 1A, and a manifold (not shown) may be provided below the plane shown in FIG. 1A. Each of the plasma zones 110_{A}-110_{D} may be parallel fluidic paths between the plenum and the manifold. The plasma zones 110_{A}-110_{D} are illustrated as cylinders in FIG. 1A in order to not obscure embodiments disclosed herein. However, it is to be appreciated that the plasma zones 110_{A}— 110_{D} have a more complex structure, as will be described in greater detail below.

In an embodiment, each of the plasma zones 110_{A}-110_{D} may be surrounded by a magnetic core 112A-112_{D}. In an embodiment, each of the magnetic cores 112 may be a ring of magnetic material that completely surrounds a perimeter of the plasma zones 110. In the illustrated embodiment, the magnetic cores 112 are square shaped rings, though it is to be appreciated that other shapes may also be used in other embodiments (e.g., circular rings, or the like). In an embodiment, the magnetic material of the magnetic cores 112 may be ferrite or other magnetic materials.

In an embodiment, the magnetic cores 112 may each be oriented on a face of a central magnetic core 108. In an embodiment, the central magnetic core 108 may be a square shaped ring. That is, there are four faces that can be adjacent to the magnetic cores 112. Since each plasma zone 110 is surrounded by a magnetic core 112, there can be a total of up to four plasma zones 110 when a square shaped ring is used for the central magnetic core 108. It is to be appreciated that other shapes may be used for the central magnetic core 108 to provide remote plasma source 100 with a different number of plasma zones 110. An example of a different shaped central magnetic core 108 is provided in greater detail below. Additionally, not all sidewalls of the central magnetic core 108 may be populated by a plasma zone 110. For example, a remote plasma source 100 with a square shaped central magnetic core 108 may include two plasma zones 110 or three plasma zones 110. Additionally, a plasma zone 110 may also be provided in the central magnetic core 108.

In an embodiment, RF coils 115 may wrap around each of the magnetic cores 112. The RF coils 115 may also wrap around the adjacent surface of the central magnetic core 108. As shown, each of the RF coils 115_{A}-115_{D} are electrically connected to each other in series. That is, an end of RF coil 115_{A} is connected to a start of RF coil 115_{B}, an end of RF coil 115E is connected to a start of RF coil 115_{C}, and an end of RF coil 115_{C} is connected to a start of RF coil 115_{D}. As will be described in greater detail below, different connection schemes between the RF coils 115_{A}-115_{D} may be used in other embodiments. Due to the radial arrangement of the magnetic cores 112 and the RF coils 115, a single power supply is able to service each of the plasma zones 110_{A}-110_{D}.

Referring now to FIG. 1B, a cross-sectional illustration of the remote plasma system along line B-B′ in FIG. 1A is shown, in accordance with an embodiment. The illustrated embodiment passes through the second plasma zone 110E and the fourth plasma zone 110_{D}. However, it is to be appreciated that other plasma zones 110_{A} and 110_{C} may have substantially similar architectures. Additionally, it is to be appreciated that fluidic paths through the plasma zones 110_{A} and 110_{C} are in parallel with the fluidic paths through the second plasma zone 110E and the fourth plasma zone 110_{D}.

As shown, a plenum 120 is provided at an upstream side of the plasma zones 110. An inlet 121 can be coupled to a gas source. In a particular embodiment, the gas source comprises NF₃. However, it is to be appreciated that the gas source may comprise any gas used in semiconductor processing environments. In an embodiment, the plenum splits that gas flow into a plurality of fluidic paths 122. For example, a fluidic path 122_{B} is routed to the second plasma zone 110_{B}, and a fluidic path 122_{D} is routed to the fourth plasma zone 110_{D}. The plenum 120 also routes gasses to the plasma zones 110 out of the plane of FIG. 1B.

In an embodiment, the plasma zones 110 are a conductive shell. Gas is allowed to flow into and out of the conductive shell through a first limiter 1091 on the upstream side of the plasma zone 110 and a second limiter 1092 on a downstream side of the plasma zone 110. The limiters 109 may have holes large enough to allow for adequate gas flows, while still confining a plasma that is struck in the space within the conductive shell. In an embodiment, the plasma is struck in the plasma zones using an RF coil 115. As shown, the RF coil 115E wraps around an edge of the magnetic core 112_{E} and the central magnetic core 108, and the RF coil 115_{D} wraps around an edge of the magnetic core 112_{D} and the central magnetic core 108.

In an embodiment, the downstream ends of the plasma zones 110 are fluidically coupled together by a manifold 125. The manifold 125 routes the fluidic paths 122_{B} and 122_{D} to a single outlet 123 that can be coupled to a processing chamber (not shown). In an embodiment, the manifold 125 also routes the downstream ends of the plasma zones 110 not shown in the cross-section of FIG. 1B.

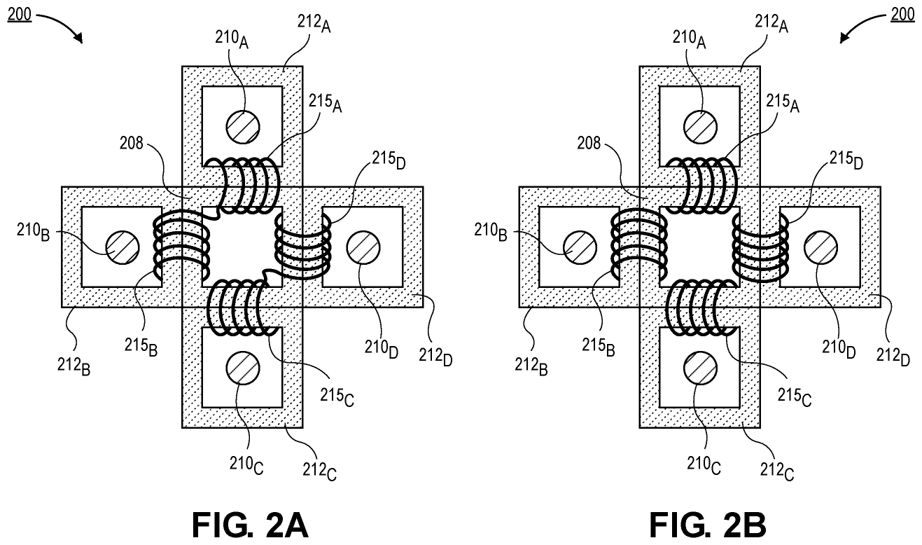

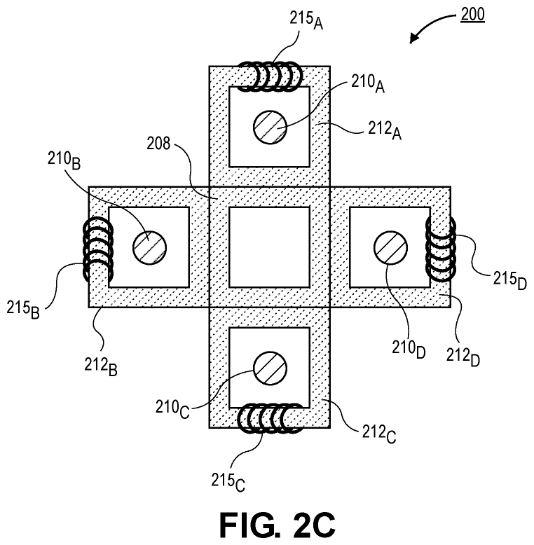

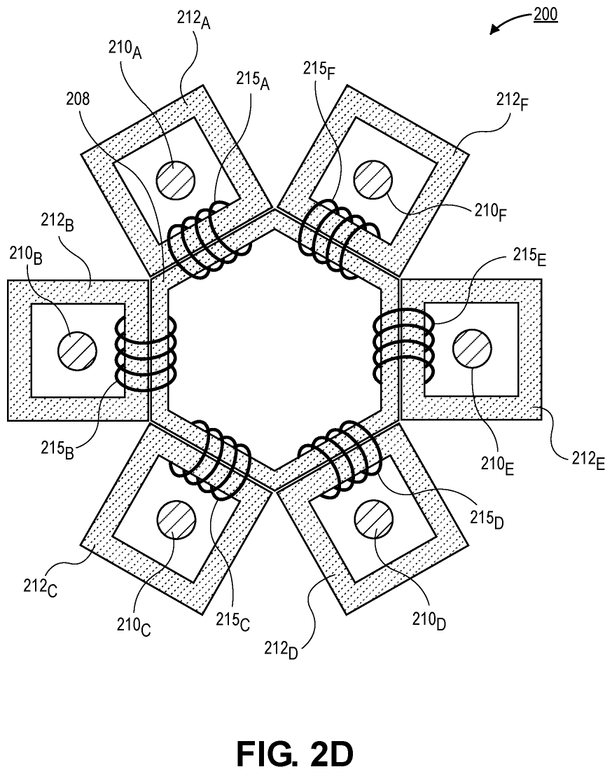

Referring now to FIG. 2A, a plan view illustration of a remote plasma system 200 is shown, in accordance with an additional embodiment. The remote plasma system 200 in FIG. 2A may be substantially similar to the remote plasma system 100 in FIG. 1A, with the exception of the configuration of the RF coils 215. That is, the remote plasma system 200 may comprise a central magnetic core 208 and a plurality of magnetic cores 212_{A}-212_{D} surrounding the central magnetic core 208. Plasma zones 210_{A}-210_{D} are provided within the magnetic cores 212_{A}-212_{D}.

The difference in FIG. 2A is how the RF coils 215 are connected. Instead of connecting all of the RF coils 215_{A}-215_{D} in series, pairs of RF coils 215 are coupled together or individually driven by the power supply or power supplies. For example, RF coil 215_{A} is connected to RF coil 215_{B}, and RF coil 215_{C} is connected to RF coil 215_{D}. In an embodiment, the pairs of RF coils (215_{A}-215_{B} and 215_{C}-215_{D}) may be connected to a single power supply in parallel. In other embodiments, different power supplies may be used for the different pairs. In some embodiments, the direction of the current within the RF coils 215 may be adjusted to enhance the field in the central magnetic core 208 to increase the overall efficiency of the units in breaking down the feed-gas in the plasma.

Referring now to FIG. 2B, a plan view illustration of a remote plasma system 200 is shown, in accordance with an additional embodiment. The remote plasma system 200 in FIG. 2B may be substantially similar to the remote plasma system 100 in FIG. 1A, with the exception of the configuration of the RF coils 215. That is, the remote plasma system 200 may comprise a central magnetic core 208 and a plurality of magnetic cores 212_{A}-212_{D} surrounding the central magnetic core 208. Plasma zones 210_{A}-210_{D} are provided within the magnetic cores 212_{A}-212_{D}.

The difference in FIG. 2B is how the RF coils 215 are connected. Instead of connecting all of the RF coils 215_{A}-215_{D} in series, each of the RF coils 215_{A}-215_{D} are electrically isolated from each other. In an embodiment, each of the RF coils 215_{A}-215_{D} may be connected to a single power supply in parallel. In other embodiments, different power supplies may be used for the different RF coils 215. In some embodiments, the direction of the current within the RF coils 215 may be adjusted to enhance the field in the central magnetic core 208 to increase the overall efficiency of the units in breaking down the feed-gas in the plasma.

Referring now to FIG. 2C, a plan view illustration of a remote plasma system 200 is shown, in accordance with an additional embodiment. The structure of the remote plasma system 200 in FIG. 2C may be substantially similar to the structure in FIG. 2B, with the exception of the location of the RF coils 215_{A}-215_{D}. Instead of being on an interior edge and wrapping around the central magnetic core 208, the RF coils 215_{A}-215_{D} are provided around outer edges of the magnetic cores 212_{A}-212_{D}. Such a configuration allows for each plasma zone 210 to operated truly independently. In the illustrated embodiment, each of the RF coils 215_{A}-215_{D} are electrically isolated from each other. However, in other embodiments, the RF coils 215_{A}-215_{D} may be connected in series, or in any other configuration.

Referring now to FIG. 2D, a plan view illustration of remote plasma source 200 is shown, in accordance with an additional embodiment. In an embodiment, the remote plasma source 200 in FIG. 2D is substantially similar to the remote plasma source 200 in FIG. 2B, with the exception of there being additional magnetic cores 212 and plasma zones 210. Particularly, the central magnetic core 208 may be a hexagonal ring. As such, there are six sidewalls to couple with plasma zones 210. As such, six plasma zones 210_{A}-210_{F} and six magnetic cores 212_{A}-212_{F} are provided in FIG. 2C. It is to be appreciated that any shaped central magnetic core 208 may be used to provide a desired number of parallel plasma zones 210. For example, a triangular central magnetic core 208 may be used to provide a three plasma zone 210 embodiment, or an octagon shaped central magnetic core 208 may be used to provide an eight plasma zone 210 embodiment. In the same fashion, the plasma source 200 may contain more sides to the central magnetic core 208 and more than eight plasma zones.

In FIG. 2D, each of the RF coils 215_{A}-215_{F} are shown as being electrically isolated from each other. In other embodiments, two or more of the RF coils 215_{A}-215_{F} may be connected together. For example, the RF coils 215_{A}-215_{F} may be connected together in pairs (e.g., 215_{A} connected to 215_{B}), or the RF coils 215_{A}-215_{F} may be connected together in groups of three (e.g., 215_{A} connected to 215_{B}, and 215_{E} connected to 215_{C}).

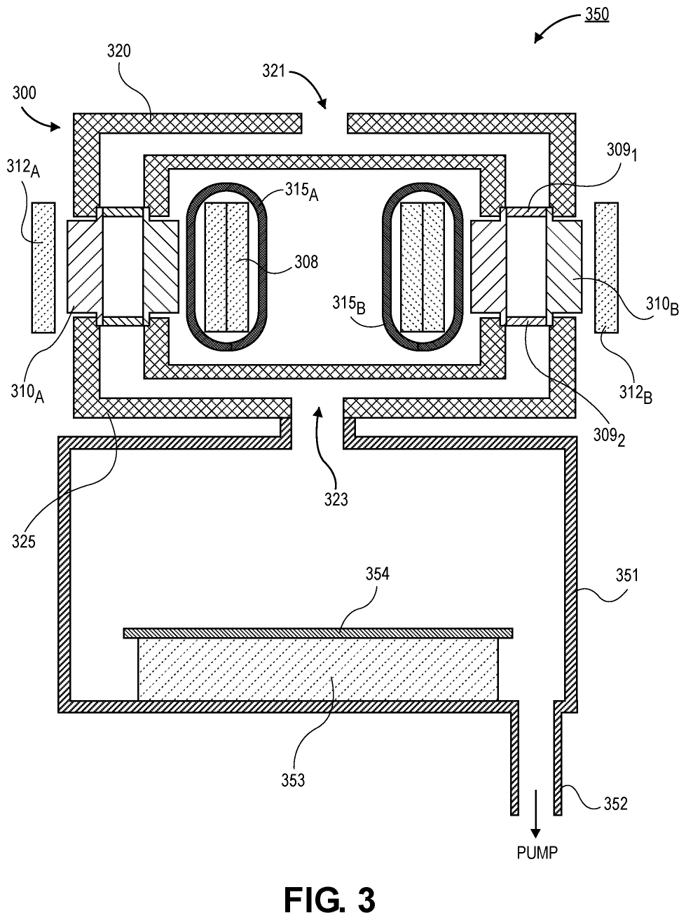

Referring now to FIG. 3, a cross-sectional illustration of a semiconductor processing tool 350 is shown, in accordance with an embodiment. In an embodiment, the semiconductor processing tool 350 comprises a remote plasma source 300 that is fluidically coupled to a chamber 351. The chamber 351 supports sub-atmospheric processing pressures. An exhaust system 352 may lead to a pump. In an embodiment, a substrate 354 is supported and secured by a chuck 353, pedestal, or the like. The substrate 354 may be a semiconductor substrate, such as a silicon wafer or other semiconductor wafer. The substrate 354 may also include glass substrates, organic substrates, or any other substrate processed in a semiconductor manufacturing environment.

In an embodiment, the processing of multiple substrates 354 over the course of time may result in the deposition of material onto the interior surfaces of the chamber 351. In an embodiment, the remote plasma source 300 may be used as part of a cleaning operation to remove unwanted depositions on the interior surfaces of the chamber 351. However, it is to be appreciated that the remote plasma source 300 may also be used for other processes in the chamber 351 as well. During the cleaning process a wafer 354 may or may not be present.

In an embodiment, the remote plasma source 300 comprises a plenum 320 that takes an input 321 and splits it into a plurality of fluidic paths to feed a plurality of plasma zones 310. For example, a pair of plasma zones 310_{A} and 310_{B} are shown. However, it is to be appreciated that any number of plasma zones 310 may be provided in parallel with each other, as described in greater detail above. In an embodiment, limiters 309₁ and 309₂ may confine the plasma within the plasma zones 310. In an embodiment, magnetic cores 312_{A} and 312_{E} surround the plasma zones 310_{A} and 310_{B}. RF coils wrap around the magnetic cores 312 and the central magnetic core 308. In an embodiment, the downstream end of the plasma zones 310 are coupled together by a manifold 325. An outlet 323 in the manifold 325 is fluidically coupled to the chamber 351.

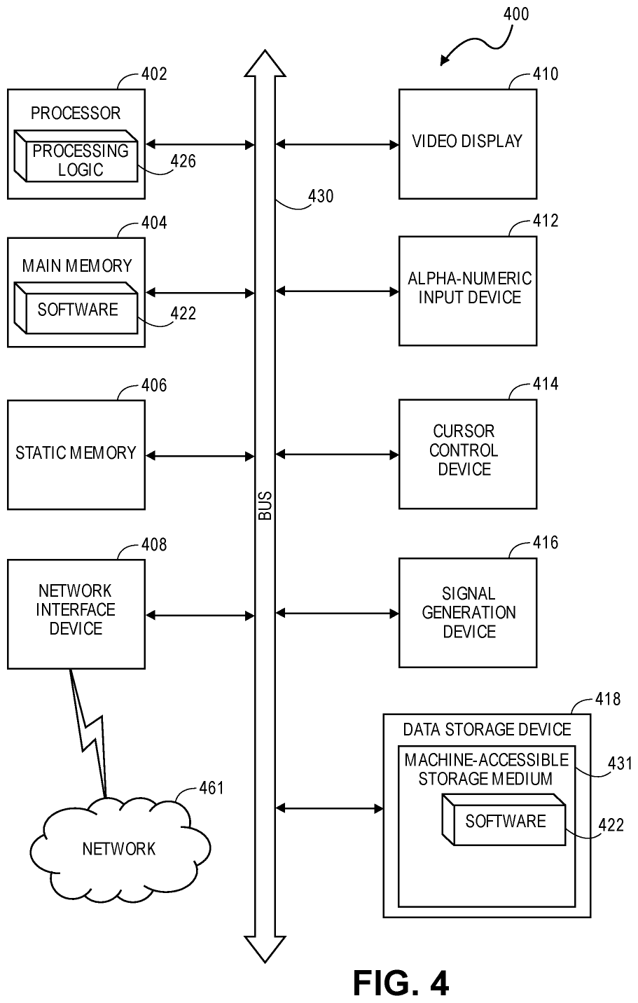

FIG. 4 illustrates a diagrammatic representation of a machine in the exemplary form of a computer system 400 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 400 includes a processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), MRAM, etc.), and a secondary memory 418 (e.g., a data storage device), which communicate with each other via a bus 430.

Processor 402 represents one or more general-purpose processing devices such as a microprocessor, central processing unit, or the like. More particularly, the processor 402 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 402 may also be one or more special-purpose processing devices such as an application specific integrated circuit (ASIC), a field programmable gate array (FPGA), a digital signal processor (DSP), network processor, or the like. Processor 402 is configured to execute the processing logic 426 for performing the operations described herein.

The computer system 400 may further include a network interface device 408. The computer system 400 also may include a video display unit 410 (e.g., a liquid crystal display (LCD), a light emitting diode display (LED), or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium (or more specifically a computer-readable storage medium) 432 on which is stored one or more sets of instructions (e.g., software 422) embodying any one or more of the methodologies or functions described herein. The software 422 may also reside, completely or at least partially, within the main memory 404 and/or within the processor 402 during execution thereof by the computer system 400, the main memory 404 and the processor 402 also constituting machine-readable storage media. The software 422 may further be transmitted or received over a network 420 via the network interface device 408.

While the machine-accessible storage medium 432 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of cleaning a processing chamber using a remote plasma source with a plurality of plasma zones where each plasma zone includes a top limiter and a bottom limiter.

Thus, methods for chamber cleaning with a remote plasma have been disclosed.

What is claimed is:

1. A plasma source, comprising:
an input to a plenum for dividing gas into a plurality of parallel fluidic paths;
a plurality of plasma zones, wherein each plasma zone is along one of the plurality of parallel fluidic paths;
a plurality of magnetic cores, wherein each magnetic core surrounds one of the plurality of plasma zones;
an RF coil wrapping around the plurality of magnetic cores; and
a manifold at a bottom of the plurality of plasma zones, wherein the manifold merges the plurality of fluidic paths into a single output.

2. The plasma source of claim 1, wherein the RF coil is a single RF coil that wraps around all of the plurality of magnetic cores.

3. The plasma source of claim 1, wherein the RF coil is a plurality of individual segments that are electrically isolated from each other, and wherein each segment wraps around one of the plurality of magnetic cores.

4. The plasma source of claim 1, further comprising:
a central magnetic core, wherein individual ones of the plurality of magnetic cores are adjacent to different sides of the central magnetic core.

5. The plasma source of claim 4, wherein the central magnetic core is square shaped, and wherein the plurality of magnetic cores comprises four magnetic cores.

6. The plasma source of claim 5, wherein the central magnetic core is hexagonal, and wherein the plurality of magnetic cores comprises six magnetic cores.

7. The plasma source of claim 5, wherein the RF coil wraps around the central magnetic core.

8. The plasma source of claim 1, wherein individual ones of the plurality of plasma zones comprise a conductive shell, a first limiter on an upstream side of the plasma zone, and a second limiter on a downstream side of the plasma zone.

9. The plasma source of claim 1, wherein the output is fluidically coupled to a plasma processing chamber.

10. The plasma source of claim 1, wherein the magnetic cores are ferrite.

11. A plasma source, comprising:
a fluidic path having an upstream side and a downstream side, wherein a plurality of fluidic segments are in parallel to each other between the upstream side and the downstream side;
a plurality of plasma zones, wherein each plasma zone is along one of the fluidic segments; and
a plurality of magnetic cores, wherein each magnetic core surrounds one of the plasma zones.

12. The plasma source of claim 11, further comprising:
an RF coil that wraps around the plurality of magnetic cores.

13. The plasma source of claim 11, further comprising:
a plurality of RF coils, wherein individual ones of the plurality of RF coils wrap around different magnetic cores.

14. The plasma source of claim 13, wherein at least two of the plurality of RF coils are electrically connected together.

15. The plasma source of claim 11, wherein the plurality of plasma zones is four plasma zones.

16. The plasma source of claim 11, wherein the plurality of plasma zones is six plasma zones.

17. The plasma source of claim 11, wherein the plurality of magnetic cores are ferrite.

18. A semiconductor processing tool, comprising:
a remote plasma source with an upstream end and a downstream end, wherein the remote plasma source comprises:
a plenum at the upstream end, wherein the plenum feeds gas to a plurality of plasma zones, wherein each plasma zone is surrounded by a magnetic core; and
a manifold at the downstream end wherein the manifold merges gas to an output; and
a chamber fluidically coupled to the outlet of the remote plasma.

19. The semiconductor processing tool of claim 18, further comprising:
an RF coil wrapping around the magnetic cores.

20. The semiconductor processing tool of claim 18, wherein the plurality of plasma zones comprises four or more plasma zones.
